(19) United States
(12) Patent Application Publication
(10) Pub. No.: US 2026/0322122 A1
(43) Pub. Date: Oct. 15, 2026

(54) REINFORCEMENT LEARNING-BASED CHARGING/DISCHARGING IMPROVEMENT METHOD FOR ENERGY STORAGE SYSTEM, AND POWER CONTROL DEVICE FOR SUPPORTING SAME

(71) Applicant: SK TELECOM CO., LTD., Seoul (KR)

(72) Inventor: Yundong SEO, Seoul (KR)

(21) Appl. No.: 19/481,439

(22) PCT Filed: May 9, 2024
(86) PCT No.: PCT/KR2024/006215

§ 371 Date: Nov. 4, 2025

(30) Foreign Application Priority Data
Jul. 4, 2023 (KR) 10-2023-0086275

(51) Int. Cl. H02J 3/00; G06N 5/04; H02J 103/30

(52) U.S. Cl. CPC H02J 3/003; G06N 5/04; H02J 3/004; H02J 2103/30

(57) ABSTRACT

A reinforcement learning-based method and a power control device supporting the method are provided for improving energy storage system (ESS) charge/discharge. This method can more flexibly apply variable prediction information and enable progressively improved ESS operation at each time step. The charge/discharge efficiency of the ESS can be progressively improved by more flexibly applying prediction information for renewable energy generation or electric vehicle charging. The method improves optimal ESS charge/discharge performance by processing prediction information and utilizing it as a state value.

### TECHNICAL FIELD

The present disclosure relates to charge/discharge control of an energy storage system, and more particularly, to reinforcement learning-based technology for controlling the charge or discharge amount of an energy storage system for each time unit.

### BACKGROUND ART

In the process of providing power generated at power plants to loads (or consumers), a proper balance between supply and demand can be maintained without power waste if the amount of power required by the load can be generated and supplied exactly. However, when utilizing power from renewable energy sources like solar or wind, where power generation is difficult to control, it is challenging to generate power in quantities that precisely match the load's requirements. To address this situation, an energy storage system (ESS) is now widely used, which can store excess power generated beyond the load's demand and provide the deficit when power generation falls short of the load's requirements.

The above-mentioned ESS is a device capable of charging energy and then discharging the charged energy depending on the intended use, and can be used to regulate the power level of a load while supporting the storage of energy for use at different time zones (e.g., time steps). The ESS can only operate in one mode: charging, which is the input of energy during a specified period of time, or discharging, which is the output of energy during a different specified period of time that does not overlap with the energy input. Furthermore, because the ESS has limited storage capacity, an efficient charging and discharging strategy is required depending on the environment in which it is used.

A conventional charge/discharge planning method for optimal ESS operation involve establishing an ESS charge/discharge plan for each time step, either 24 hours a day or for a planned time interval, and operating the ESS according to the plan. If the target power to be controlled through ESS charge/discharge includes variable power sources such as renewable energy generation and electric vehicle charging, prediction information on these power sources is additionally incorporated to mitigate uncertainty in establishing the optimal ESS charge/discharge plan. However, because renewable energy generation requires accurate estimation of natural phenomena and electric vehicle charging requires accurate estimation of charging patterns of an unspecified number of users, prediction errors occur even when very advanced prediction technique is applied.

Moreover, in the conventional technique, the predicted results for respective time steps are used as inputs for the ESS charge/discharge plan according to the corresponding time steps. However, even if the daily average prediction accuracy is high, if the prediction error of certain time steps is large, the charge/discharge plan for that time steps is likely not to be planned with appropriate values. In addition, the ESS cannot continuously receive energy from the outside, it can only discharge as much as it has been charged, and its storage capacity is limited. Consequently, an inappropriate charge/discharge plan for certain time steps may cause the energy storage capacity to be charged or discharged to its limit early during the charge/discharge of the subsequent time step, resulting in a problem where the necessary charge/discharge cannot be performed.

### SUMMARY

Accordingly, the present disclosure is intended to provide a reinforcement learning-based method for improving ESS charge/discharge, along with a power control device supporting the method. This method can more flexibly apply variable prediction information and enable progressively improved ESS operation at each time step.

Furthermore, the present disclosure is intended to provide a reinforcement learning-based method for improving ESS charge/discharge, along with a power control device supporting the method, which utilizes prediction information as state values to achieve optimal ESS charge/discharge performance.

However, the objects of the present disclosure are not limited to the above-mentioned objects, and other objects that are not mentioned can be clearly understood from the following description.

In order to accomplish the above object, a power control device for performing power control of an energy storage system (ESS) device may include a server communication circuit configured to form a communication channel with a renewable power plant, a customer, the ESS device, and an external information providing server, a server memory, and a server processor functionally connected to the server communication circuit. The sever processor may be configured to collect a current power generation amount of the renewable power plant, a current load power amount of the consumer, state information of the ESS device, and environmental information related to power generation of the renewable power plant provided by the external information providing server, to acquire, based on data pre-stored in the server memory, a past power generation amount and a past load power amount in a past external information situation matched to the external information, to calculate current prediction data of a predefined reference time unit by comparing the acquired past power generation amount and the acquired past load power amount with the current power generation amount and the current load power amount, to process the current prediction data as an input for an artificial intelligence model based on reinforcement learning, to perform inference, and to perform training for generating a charge/discharge command of the ESS device based on a result of the inference.

Specifically, the server processor may be configured to calculate a reward value for a previously applied charge/discharge command of the ESS device based on at least some of the current power generation amount of the renewable power plant, the current load power amount of the consumer, and the state information of the ESS device.

Specifically, the server processor may be configured to perform preprocessing on the prediction data and then process the preprocessed prediction data as the input for the artificial intelligence model.

Specifically, the server processor may be configured to calculate, as the preprocessed prediction data, at least one of an average of current prediction data for a reference time unit, a difference between current prediction data for the reference time unit and prediction data for at least one previous reference time unit, and a sum of current prediction data for the reference time unit and prediction data for at least one previous reference time unit.

Specifically, the server processor may be configured to calculate, as the preprocessed prediction data, at least one of an increase, decrease, and maintenance of data and at least one of a slope value of the increase or decrease, based on prediction data of a plurality of reference time units including the prediction data.

Specifically, the server processor may be configured to perform a post-processing that limits the artificial intelligence model inference to a preset maximum and minimum value range.

Specifically, the server processor may be configured to calculate the prediction data based on a learning-completed artificial intelligence model, provide the prediction data to the ESS device, and if the prediction data calculation satisfies a specified condition, generate a new artificial intelligence model based on reinforcement learning.

According to an embodiment of the present disclosure, a method for performing power control of an energy storage system (ESS) device may include, by a server processor of a power control device, collecting a current power generation amount of a renewable power plant, a current load power amount of a consumer, state information of the ESS device, and environmental information related to power generation of the renewable power plant; acquiring, based on data pre-stored in a server memory of the power control device, a past power generation amount and a past load power amount in a past external information situation matched to external information; calculating current prediction data of a predefined reference time unit by comparing the acquired past power generation amount and the acquired past load power amount with the current power generation amount and the current load power amount; processing the current prediction data as an input for an artificial intelligence model based on reinforcement learning; performing inference on input processing of the artificial intelligence model; and performing training for generating a charge/discharge command of the ESS device based on a result of the inference.

Specifically, the method may further include calculating a reward value for a previously applied charge/discharge command of the ESS device based on at least some of the current power generation amount of the renewable power plant, the current load power amount of the consumer, and the state information of the ESS device, and the calculated reward value may be applied to performing the inference.

Specifically, processing as the input for the artificial intelligence model may includes performing preprocessing on the prediction data and then processing the preprocessed prediction data as the input for the artificial intelligence model.

Specifically, processing the preprocessed prediction data as the input for the artificial intelligence model may include calculating, as the preprocessed prediction data, at least one of an average of current prediction data for a reference time unit, a difference between current prediction data for the reference time unit and prediction data for at least one previous reference time unit, and a sum of current prediction data for the reference time unit and prediction data for at least one previous reference time unit.

Specifically, processing the preprocessed prediction data as the input for the artificial intelligence model may include calculating, as the preprocessed prediction data, at least one of an increase, decrease, and maintenance of data and at least one of a slope value of the increase or decrease, based on prediction data of a plurality of reference time units including the prediction data.

Specifically, the method may further include performing a post-processing that limits the artificial intelligence model inference to a preset maximum and minimum value range.

Specifically, the method may further include calculating the prediction data based on a learning-completed artificial intelligence model, providing the prediction data to the ESS device, and if the prediction data calculation satisfies a specified condition, generating a new artificial intelligence model based on reinforcement learning.

According to the present disclosure, the charge/discharge efficiency of the ESS can be progressively improved by more flexibly applying prediction information for renewable energy generation or electric vehicle charging.

Additionally, the present disclosure can provide a method for improving optimal ESS charge/discharge performance by processing prediction information and utilizing it as a state value.

Further, various effects other than the above-mentioned effects can be directly or implicitly disclosed in the detailed description according to embodiments of the present disclosure to be described later.

### DESCRIPTION OF DRAWINGS

FIG. 1 is a diagram illustrating an example of an improved charge/discharge environment for an ESS device according to an embodiment of the present disclosure.

FIG. 2 is a diagram illustrating an example configuration of a power control device according to an embodiment of the present disclosure.

FIG. 3 is a diagram illustrating an example configuration of a server processor of a power control device according to an embodiment of the present disclosure.

FIG. 4 is a diagram illustrating an example configuration of an AI ESS charge/discharge command generator according to an embodiment of the present disclosure.

FIG. 5 is a diagram illustrating an example of data input for a reinforcement learning AI model according to an embodiment of the present disclosure.

FIG. 6 is a diagram illustrating another example of data input for a reinforcement learning AI model according to an embodiment of the present disclosure.

FIG. 7 is a diagram illustrating the charge/discharge results of an example of ESS control based on a prediction of solar power generation and electric vehicle charging power.

FIG. 8 is a diagram illustrating the charge/discharge results of an example of reinforcement learning-based ESS device control based on a prediction of solar power generation and electric vehicle charging power based on according to an embodiment of the present disclosure.

FIG. 9 is a diagram illustrating the charge/discharge results of another example of ESS device control based on a prediction of solar power generation and electric vehicle charging power.

FIG. 10 is a diagram illustrating the charge/discharge results of another example of reinforcement learning-based ESS device control based on a prediction of solar power generation and electric vehicle charging power based on according to an embodiment of the present disclosure.

FIG. 11 is a diagram illustrating an example of an AI modeling method related to reinforcement learning-based ESS charge/discharge control according to an embodiment of the present disclosure.

FIG. 12 is a diagram illustrating an example of a method for improving ESS device charge/discharge using a reinforcement learning-based AI model according to an embodiment of the present disclosure.

### DETAILED DESCRIPTION

Now, embodiments of the present disclosure will be described in detail with reference to the accompanying drawings.

However, in the following description and the accompanying drawings, well known functions and components may not be described nor illustrated in detail to avoid obscuring the subject matter of the present disclosure. In addition, identical components are indicated with the same reference numerals as much as possible throughout the drawings The terms or words used in the following description and drawings should not be interpreted as limited to their usual or dictionary meanings and should be interpreted as meanings and concepts that conform to the technical idea of the present disclosure based on the principle that the inventor can appropriately define the concept of the terms to best describe his or her disclosure. Therefore, embodiments described herein are only the most preferred embodiments of the present disclosure and do not represent all of the technical ideas of the present disclosure. Thus, it should be understood that there may be various equivalents and modified examples that can replace the embodiments at the time of filing this application.

In addition, terms including ordinal numbers such as first, second, etc. are used to describe various elements only for the purpose of distinguishing one element from another, and are not used to limit such elements. For example, without departing from the scope of the present disclosure, a second element may be named a first element, and similarly, a first element may also be named a second element.

In addition, terms used herein are only for describing specific embodiments and do not limit the present disclosure. The singular expression includes the plural expression unless the context clearly indicates otherwise. Also, the terms such as “comprise” and “include” used herein are intended to specify the presence of features, numerals, steps, operations, elements, components, or combinations thereof, which are disclosed herein, and should not be construed to exclude in advance the possibility of the presence or addition of other features, numerals, steps, operations, elements, components, or combinations thereof.

In addition, the terms such as “unit” and “module” used herein refer to a unit that processes at least one function or operation and may be implemented with hardware, software, or a combination of hardware and software. In addition, the terms “a”, “an”, “one”, “the”, and similar terms may be used as both singular and plural meanings in the context of describing the present disclosure (especially in the context of the following claims) unless the context clearly indicates otherwise.

In addition to the terms mentioned above, specific terms used in the following description are provided to help understanding of the present disclosure, and the use of such specific terms may be changed to other forms without departing from the technical meaning of the present disclosure.

Also, embodiments within the scope of the present disclosure include computer-readable media having computer-executable instructions or data structures stored on computer-readable media. Such computer-readable media can be any available media that is accessible by a general purpose or special purpose computer system. By way of example, such computer-readable media may include, but not limited to, RAM, ROM, EPROM, CD-ROM or other optical disk storage, magnetic disk storage or other magnetic storage devices, or any other physical storage medium that can be used to store or deliver certain program codes formed of computer-executable instructions, computer-readable instructions or data structures and which can be accessed by a general purpose or special purpose computer system.

Herein, reinforcement learning applied to the method for improving ESS charge/discharge performance of the present disclosure is a field of machine learning where an agent performs an action in a given environment and learns by receiving a reward from the outcome. For instance, in reinforcement learning, an agent selects an action in a given environment, the environment changes in response to that action, and a reward is given. To maximize the reward, the agent learns by adjusting and improving its actions over time. To this end, reinforcement learning applies state, action, reward, policy, value, and value function. The ESS charge/discharge environment to which the aforementioned reinforcement learning is applied provides a method for establishing a charge/discharge plan for a day or a time interval (e.g., a series of consecutive time steps) and operating the ESS accordingly so that it can perform optimal charging and discharging.

Now, the types and roles of components included in a power control device that supports the improvement of ESS's charge/discharge based on reinforcement learning according to the present disclosure will be described.

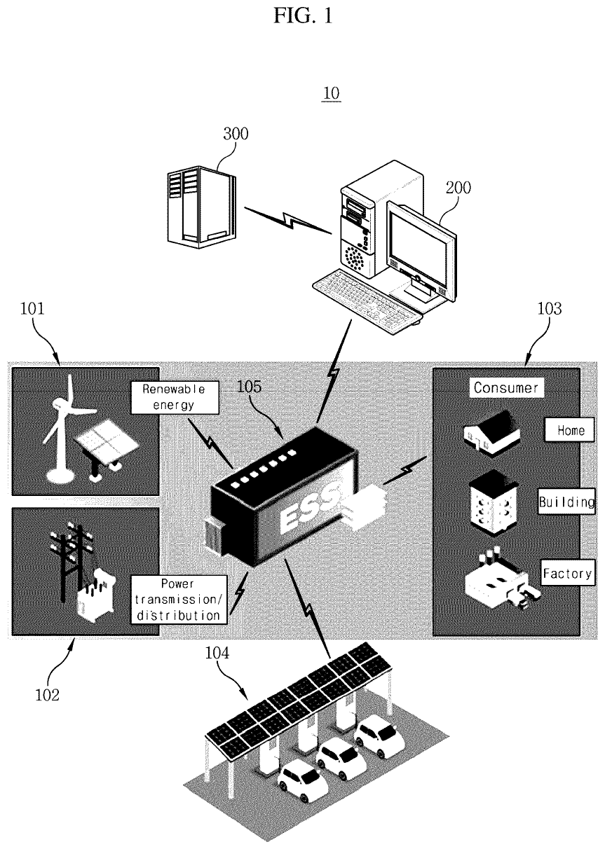

FIG. 1 is a diagram illustrating an example of an improved charge/discharge environment for an ESS according to an embodiment of the present disclosure.

Referring to FIG. 1, the ESS device charge/discharge improvement environment 10 according to an embodiment of the present disclosure may include a renewable power plant 101, a power transmission/distribution unit 102, a consumer 103, a vehicle charge/discharge unit 104, an ESS device 105, an external information providing server 300, and a power control device 200. Meanwhile, at least one of the above-listed components of the ESS device charge/discharge improvement environment 10 may be excluded. For example, at least one of the vehicle charge/discharge unit 104 and the power transmission/distribution unit 102 may be omitted in the ESS device charge/discharge improvement environment 10. In addition, the ESS device charge/discharge improvement environment 10 may include a network for signal transmission and reception between at least one of the renewable power plant 101, the power transmission/distribution unit 102, and the consumer 103 and the ESS device 105, between the vehicle charge/discharge unit 104 and the ESS device 105, and/or between the ESS device 105, the external information providing server 300, and the power control device 200. This network may be configured to support at least one of a wired or wireless scheme and, even in the wireless scheme, support at least one of various communication schemes or communication types. In addition, the network may support signal transmission and reception between a power control system and the ESS device 105. Meanwhile, in FIG. 1, the ESS device 105 and the power control device 200 are illustrated as being separated and connected through a network, but the present disclosure is not limited thereto. For example, the power control device 200 may be configured to form a communication channel with the renewable power plant 101, the power transmission/distribution unit 102, the consumer 103, and the vehicle charge/discharge unit 104, to collect and analyze data (or information) from at least one of the renewable power plant 101, the power transmission/distribution unit 102, the consumer 103, and the vehicle charge/discharge unit 104, and to control the charge/discharge of the ESS device 105 based on reinforcement learning. Alternatively, the power control device 200 and the ESS device 105 may be configured as an integrated component.

The consumer 103 may be an entity that receives and consumes electricity. The consumer 103 may refer to, for example, a power-consuming facility such as a building or factory, at least one home or office that consumes electricity, or at least one specific area that consumes electricity. Alternatively, the consumer 103 may include power meters in various buildings or devices that utilize high power (e.g., heating and cooling systems, industrial equipment). As such, the consumer 103 is a component that receives and consumes electricity and is not limited to a specific form, size, shape, or location. In terms of the ESS device 105, the consumer 103 may correspond to a load power source or a power demand source.

The renewable power plant 101 may include a power plant that produces at least one type of renewable energy. For example, the renewable power plant 101 may include at least one of a wind power plant, a solar thermal or photovoltaic power plant, a tidal power plant, a hydroelectric power plant, or a geothermal power plant. As described above, the renewable power plant 101 may include a power plant whose power generation is affected by the surrounding weather or environment.

The power transmission/distribution unit 102 may include a transmission and distribution unit 102 of a power plant capable of generating a fixed amount of power. For example, the power transmission/distribution unit 102 may include at least one of a fossil fuel power plant and a nuclear power plant.

The vehicle charge/discharge unit 104 may include a combination of a charging station capable of charging at least one vehicle and a power plant capable of generating power from at least one of solar energy and solar heat. The vehicle charge/discharge unit 104 may be considered as a component of the consumer 103 in terms of charging at least one vehicle, and may be considered as a component of the renewable power plant 101 in terms of generating power from solar energy and solar heat. Furthermore, the vehicle charge/discharge unit 104 may include an energy storage device for vehicle charging. As described above, the vehicle charge/discharge unit 104 may be considered as a component in which at least two of the renewable power plant 101, the consumer 103, and the ESS device 105 are integrated in a composite form.

The ESS device 105 can perform a charging operation or a discharging operation in response to the control of the power control device 200. The ESS device 105 may include a battery module capable of storing energy, a charge circuit capable of charging the battery module, a discharge circuit capable of discharging power stored in the battery module, and a control circuit for communicating with the power control device 200 and operating the charge circuit or the discharge circuit in response to a control signal of the power control device 200. In an example, the ESS device 105 can supply stored power to the consumer 103 for a certain period of time in response to the control of the power control device 200. Also, in response to the control of the power control device 200, the ESS device 105 can receive power from the renewable power plant 101 or the power transmission/distribution unit 102 and charge the battery module. In this regard, the ESS device 105 may include power supply wiring capable of supplying power to the consumer 103, and power reception wiring capable of receiving power from the renewable power plant 101 or the power transmission/distribution unit 102. In addition, the ESS device 105 may include wiring for transmitting and receiving power to and from the vehicle charge/discharge unit 104.

The external information providing server 300 may include a server device that provides external information to the power control device 200. For example, the external information providing server 300 may provide the power control device 200 with weather and other surrounding environmental information of the area where the renewable power plant 101 is located. In addition, the external information providing server 300 may provide the power control device 200 with information related to the vehicle charge/discharge unit 104 (e.g., electric vehicle operation information around the vehicle charge/discharge unit 104).

The power control device 200 may control the ESS device 105 to charge or discharge according to the received power or generated power of a certain time interval (e.g., a plurality of consecutive time steps) based on the received power data (e.g., the received power data of at least one of the consumer 103 and the vehicle charge/discharge unit 104) and the generated power data (e.g., the generated power data of at least one of the renewable power plant 101 and the power transmission/distribution unit 102) collected in real time. In this process, the power control device 200 may control the charging and discharging operations of the ESS device 105 to be performed more effectively based on reinforcement learning. For example, the power control device 200 may determine the charging or discharging operation of the ESS device 105 by collecting power demand (or load power) and calculating a power demand prediction value (or load power prediction value) in at least one predefined time unit (or daily unit) (e.g., time step). Also, the power control device 200 may perform the charging operation of the ESS device 105 by collecting the generated power amount and the generated power prediction amount in at least one predefined time unit (e.g., time step). In this process, the power control device 200 may perform reinforcement learning to control the charging and discharging operations of the ESS device 105 in a direction that generates the maximum profit based on at least one time unit (or a certain accumulated time unit), or may perform reinforcement learning to control them in a direction that generates the minimum loss based on at least one time unit (or a certain accumulated time unit).

As described above, the ESS device charge/discharge improvement environment 10 of the present disclosure performs either the charging operation or the discharging operation of the ESS device 105, based on the amount of power (or power demand, load power) or the amount of predicted power (or power demand prediction value, load power prediction value) supplied to the consumer 103 and the vehicle charge/discharge unit 104, and the amount of power generated (or power generation amount) or the amount of predicted power generated (or predicted power generation amount) to be provided through at least one of the renewable power plant 101 and the power transmission/distribution unit 102, and performs reinforcement learning control for at least one time unit (e.g., time step) (or accumulated time unit) for maximum profit or minimum loss, thereby supporting the effective operation of the ESS device 105.

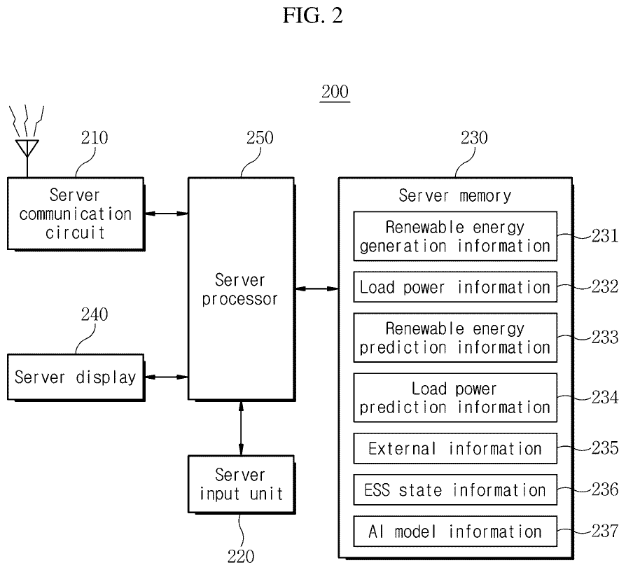

FIG. 2 is a diagram illustrating an example configuration of a power control device according to an embodiment of the present disclosure.

Referring to FIGS. 1 and 2, the power control device 200 according to an embodiment of the present disclosure may include a server communication circuit 210, a server input unit 220, a server memory 230, a server display 240, and a server processor 250.

The server communication circuit 210 may form a communication channel of the power control device 200. The server communication circuit 210 may form a communication channel with the renewable power plant 101, the power transmission/distribution unit 102, the vehicle charge/discharge unit 104, the consumer 103, and the ESS device 105, and may receive state information of the respective components (e.g., the renewable power plant 101, the power transmission/distribution unit 102, the vehicle charge/discharge unit 104, the consumer 103, and the ESS device 105) in real time or according to a predefined criterion (e.g., a time step). Additionally or alternatively, the server communication circuit 210 may receive information on the predicted amount (e.g., at least one of the predicted power amount and the predicted power generation amount) of the respective components (e.g., the renewable power plant 101, the power transmission/distribution unit 102, the vehicle charge/discharge unit 104, the consumer 103, and the ESS device 105).

The server input unit 220 may receive an administrator's input required for the operation of the power control device 200. For example, the server input unit 220 may receive an administrator's input for setting the minimum energy storage amount (or minimum value) or maximum energy storage amount (or maximum value) of the ESS device 105. Also, the server input unit 220 may receive an administrator's input for requesting the output of information related to the operation of the ESS device 105. In this regard, the server input unit 220 may include at least one of a physical key, a touch key, a touch screen, a voice input device, a gesture input device, a jog shuttle, and a jog key for an administrator's input.

The server memory 230 may store data or programs related to the operation of the power control device 200. For example, the server memory 230 may include renewable energy generation information 231, load power information 232 (or demand power information), renewable energy prediction information 233, load power prediction information 234, external information 235, ESS state information 236, and artificial intelligence (AI) model information 237. The renewable energy generation information 231 is information on the amount of current power generation of the renewable power plant 101, and may be collected and updated in real time. The load power information 232 may include the size of current load power used by the consumer 103. Additionally or alternatively, the load power information 232 may include the size of load power used for vehicle charging by the vehicle charge/discharge unit 104. The renewable energy prediction information 233 may include a predicted amount of renewable energy generation within a future reference time unit (e.g., time step) that the renewable power plant 101 can generate in response to the external information 235. Considering a situation in which load power may change due to the external information 235, the load power prediction information 234 may include predicted information that predicts the amount of load power that will change within a future reference time unit due to the external information 235. The external information 235 is information including a value of a change in the surrounding weather or environment. The external information 235 may include information provided by the external information providing server 300 that includes at least one of public data or a specific observatory that observes the surrounding environment. The external information 235 may include information on electric vehicles running around the vehicle charge/discharge unit 104. The ESS state information 236 may include state information of the ESS device 105. The AI model information 237 may include information regarding modeling for supporting reinforcement learning according to an embodiment of the present disclosure. In the above-described information, the prediction information may include information predicted based on information collected by the power control device 200. Also, the prediction information may include information predicted by each of the components, for example, the renewable power plant 101, the consumer 103, or the vehicle charge/discharge unit 104. In this regard, each of the components (e.g., at least one of the renewable power plant 101, the consumer 103, and the vehicle charge/discharge unit 104) may include a communication module capable of collecting the external information 235, a processor capable of calculating prediction information to occur within a future reference time (e.g., Time step) based on the collected external information 235, and a memory for storing programs for each operation and data processing.

The server display 240 may output at least one screen related to the operation of the power control device 200. For example, the server display 240 may output a screen including at least one of the connection state with at least one of the components (e.g., the renewable power plant 101, the power transmission/distribution unit 102, the vehicle charge/discharge unit 104, the consumer 103, and the ESS device 105), the operation state of each component, real-time information provided by each component, and prediction information provided by each component. The server display 240 may output at least one of a screen for generating commands related to controlling the ESS device 105 based on real-time information and predicted information received from at least one of the above-described components (e.g., the renewable power plant 101, the power transmission/distribution unit 102, the vehicle charge/discharge unit 104, the consumer 103, and the ESS device 105), and a screen for displaying a situation in which the ESS device 105 performs a charging or discharging operation according to a message including the generated command. The server display 240 may output information that records the operating state of the ESS device 105 at a predetermined reference time unit (e.g., time step).

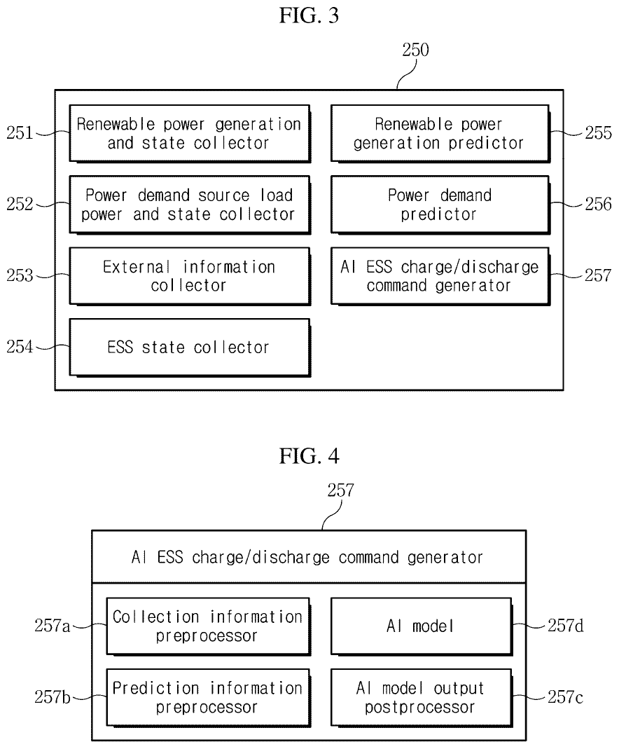

The server processor 250 may perform at least one of transferring and processing a signal related to the operation of the power control device 200, and outputting or storing a result of the processing. For example, the server processor 250 may collect at least one of the power generation amount of a power generation member (e.g., at least one of the renewable power plant 101, the power transmission/distribution unit 102, and the vehicle charge/discharge unit 104) that supplies power to the ESS device 105, load power (e.g., at least one of the consumer 103 and the vehicle charge/discharge unit 104) that receives power from the ESS device 105, and the external information 235, and it may calculate a predicted amount based on the collected information. Here, if the power generation member (e.g., the renewable power plant 101 or a power generating portion of the vehicle charge/discharge unit 104) or the load power (e.g., the consumer 103 or a vehicle charging portion of the vehicle charge/discharge unit 104) is designed to directly calculate the predicted amount and provide it to the power control device 200, the server processor 250 may omit the predicted amount calculation operation and collect predicted amount information from the corresponding components at regular intervals. The server processor 250 may perform reinforcement learning by applying the AI model information to the collected information, and based on the results, control at least one of the charging and discharging operations of the ESS device 105. In this regard, the server processor 250 may include a configuration as illustrated in FIG. 3.

Meanwhile, in the above description, the power control device 200 for ESS charge/discharge control based on reinforcement learning includes the vehicle charge/discharge unit 104 and the power transmission/distribution unit 102, but the present disclosure is not limited thereto. For example, the power control device 200 may perform reinforcement learning-based ESS device 105 control in an environment where at least one of the vehicle charge/discharge unit 104 and the power transmission/distribution unit 102 is excluded.

FIG. 3 is a diagram illustrating an example configuration of a server processor of a power control device according to an embodiment of the present disclosure.

Referring to FIG. 3, the server processor 250 may include a renewable power generation and state collector 251, a power demand source load power and state collector 252, an external information collector 253, an ESS state collector 254, a renewable power generation predictor 255, a power demand predictor 256, and an AI ESS charge/discharge command generator 257 (or a command generation device).

The renewable power generation and state collector 251 may collect in real time the external information 235 including weather information (temperature, humidity, wind, etc.) surrounding the renewable power source and the power generation amount of the renewable power plant 101. In this regard, the renewable power generation and state collector 251 may be connected through a network to a public data provision device or a specific weather web server that provides the external information 235, and it may collect the external information 235 in real time or at regular intervals. In this process, based on information about the area where the renewable power plant 101 is located, the renewable power generation and state collector 251 may collect weather information surrounding the corresponding location as the external information 235. In addition, the renewable power generation and state collector 251 may be connected to the renewable power plant 101 through a network and collect information on the amount of real-time power generation from the renewable power plant 101.

The power demand source load power and state collector 252 may collect in real time the state information and load power of the consumer 103 connected via a network. In this regard, the consumer 103 may include a control device that collects and provides state information and load power of a building power meter or a device that uses high power (such as heating and cooling, electric vehicle charging, and industrial equipment).

The renewable power generation predictor 255 may predict the generation amount of the renewable power plant 101 based on the external information 235. In this regard, the renewable power generation predictor 255 may identify the external information 235 stored in the server memory 230, and obtain information on the current generation amount of the renewable power plant 101 from the renewable energy generation and state collector 251. The renewable power generation predictor 255 may store and manage accumulated information on changes in the power generation amount of the renewable power plant 101 according to the external information 235. For example, the renewable power generation predictor 255 may pre-store and manage historical information on how much power the renewable power plant 101 can generate, depending on at least one of season, day, time, weather conditions (such as cloud cover, humidity, wind, etc.), and external temperature. In an example, since the power generation of renewable energy fluctuates depending on external weather conditions, the renewable power generation predictor 255 may predict the power generation amount within the next 24 hours or several hours at each preset time unit (e.g., time step) by referring to the weather conditions.

The power demand predictor 256 may predict the load power of the consumer 103 (or individual or all power demand sources) connected to the power demand source load power and state collector 252. The power demand predictor 256 may predict the load power within the next 24 hours or several hours at each preset time step by referring to the collected state information to reflect the characteristics of individual power demand sources (or the consumer 103). In this regard, the power demand predictor 256 may store and manage the previous seasonal, daily, and hourly power usage history of the consumer 103.

The external information collector 253 may collect, in addition to facility information connected to the power control device 200, public data such as power grid information and weather information, or setting information required for operation by an operator, from the external information providing server 300. In this regard, the external information collector 253 may pre-store and manage web address information or server address information for collecting the external information 235, and check for updates in real time or at regular intervals. If any information update occurs, the external information collector 253 may collect the updated information and report it to the renewable power generation predictor 255 and the power demand predictor 256.

The ESS state collector 254 may collect state information of the ESS device 105 from the ESS device 105. In this regard, the ESS state collector 254 may form a communication channel with the ESS device 105 and collect the state information of the ESS device 105 in real time or at a certain time unit (e.g., time step). The state information of the ESS device 105 may include, for example, at least one of the remaining charge level stored in the ESS, ESS operation state, voltage, current, and output.

The AI ESS charge/discharge command generator 257 may preprocess real-time information collected by various collectors and predicted information predicted by predictors at each preset time step, input the preprocessed information into the AI model, and post-process the output information to generate the final ESS charge/discharge command. Here, the preset time unit (e.g., time step) may be changed by an administrator or set statistically or empirically. For example, the time unit may be set in various hour units such as 1 hour, 2 hours, 4 hours, or in various minute units such as 1 minute or 5 minutes. The AI ESS charge/discharge command generator 257 may include a configuration as illustrated in FIG. 4 in relation to command generation.

FIG. 4 is a diagram illustrating an example configuration of an AI ESS charge/discharge command generator according to an embodiment of the present disclosure.

Referring to FIG. 4, the AI ESS charge/discharge command generator 257 may include a collection information preprocessor 257a, a prediction information preprocessor 257b, an AI model 257d (e.g., the AI model information 237 stored in the server memory 230), and an AI model output postprocessor 257c.

The collection information preprocessor 257a may generate additional information such as increase, decrease, and average by storing several past time steps of some of the collected information and calculating the average, difference, sum, etc. of the collected information. For example, the collection information preprocessor 257a may calculate, for the real-time power generation amount provided by at least one of the renewable power plant 101 and the vehicle charge/discharge unit 104, the time-unit-specific average, the difference between the previous time unit and the current time unit, or the sum in a certain number of time units. Also, the collection information preprocessor 257a may store several past time steps (or time units) for the real-time power generation amount provided by at least one of the renewable power plant 101 and the vehicle charge/discharge unit 104, determine the trend of the stored data, and produce information such as whether it is increasing, decreasing, or maintaining, or output the trend as a slope value. In addition, the collection information preprocessor 257a may calculate at least one of the above-described average, difference, and sum for the load power used in at least one of the consumer 103 and the vehicle charge/discharge unit 104. For example, the collection information preprocessor 257a may determine the increase, decrease, and maintenance state of the load power used in at least one of the consumer 103 and the vehicle charge/discharge unit 104, and produce a numerical value corresponding to each change value.

Like the above-described collection information preprocessor 257a, the prediction information preprocessor 257b may generate additional information such as increase, decrease, and maintenance by storing several past or future time steps of some prediction information and calculating the average, difference, sum, etc. of the prediction information. For example, the prediction information preprocessor 257b may calculate, for the prediction amount of the new renewable power plant 101, at least one of the average, difference, and sum for at least one time unit, based on the external information 235. Also, based on the external information 235, the prediction information preprocessor 257b may calculate state information or change values corresponding to at least one of increase, decrease, and maintenance for the prediction amount of the new renewable power plant 101. In relation to the vehicle charge/discharge unit 104, the prediction information preprocessor 257b may calculate the state of either the vehicle charging operation or power generation operation of the vehicle charge/discharge unit 104 based on the external information 235 (e.g., electric vehicle operation information and weather information), the average, difference, or sum of the load power used to charge the vehicle for at least one time unit during the vehicle charging operation, and the change amount of the load power within a plurality of time units. Also, the prediction information preprocessor 257b may calculate the change value (e.g., average, difference, or sum) in the power generation amount for at least one time unit or the change value of the power generation amount for a plurality of time units during the power generation operation of the vehicle charge/discharge unit 104.

The AI model output postprocessor 257c may limit the value output from the AI model information 237 to the maximum/minimum value set by an administrator of the power control device 200, or adjust the size in consideration of the operating state of the ESS device 105. For example, the AI model output postprocessor 257c may obtain the AI model 257d from the AI model information 237, and in the process of performing reinforcement learning based on the obtained AI model 257d, it may control the ESS device 105 to be charged to the maximum value or less during the charging operation, and control the ESS device 105 to be discharged to the minimum value or more during the discharging operation.

The AI model 257d refers to a model trained through reinforcement learning, which is a category of machine learning in the present disclosure, and may refer to a model trained (or learned) for the purpose of maximizing cumulative profit or minimizing cumulative loss for 24 hours or a set time interval (e.g., multiple consecutive time steps) of a system that the power control device 200 is to control. For example, reinforcement learning is not a method of having to derive the entire plan of the set future time range all at once, but a method of learning an action that maximizes the cumulative reward of the set time range by considering the surrounding situation at each time step. Therefore, the power control device 200 of the present disclosure can train and infer a reinforcement learning model even without directly using the values for each time step of renewable energy generation and demand power prediction. In addition, considering the limited battery capacity of the ESS device 105, it is important not only to determine the charge/discharge size for each time step, but also to properly distribute the available charging and discharging capacity. This enables the optimal ESS charge/discharge that can avoid ESS charge/discharge failure due to early full charge or discharge. In this regard, the AI ESS charge/discharge command generator 257 may obtain data that can be referenced for learning to satisfy surrounding situations and constraints for each time step when training the reinforcement learning model. The data may use information obtained from the renewable power generation and state collector 251, the power demand source load power and state collector 252, the external information collector 253, and the ESS state collector 254. In addition, data that can be referenced for learning the appropriate distribution of the ESS device 105 capacity for the future time may use information from the renewable power generation predictor 255 and the power demand predictor 256. For the optimal ESS charge/discharge learning using reinforcement learning, prediction information on renewable energy generation and power demand may be used for each time step as in a mathematical/deterministic optimization technique, but all prediction information from the time step to the last time step can be input into the reinforcement learning model to better distribute appropriately the capacity of the ESS device 105 for the future time.

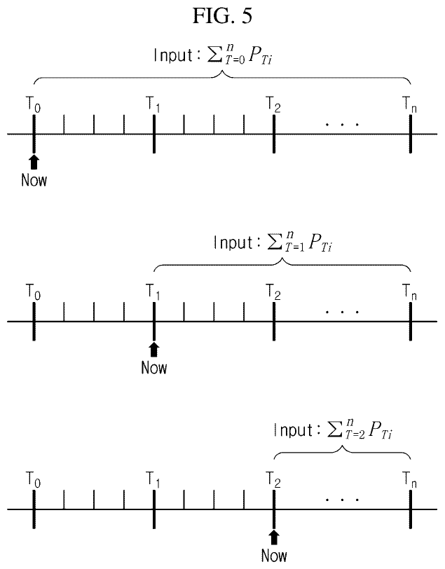

FIG. 5 is a diagram illustrating an example of data input for a reinforcement learning AI model according to an embodiment of the present disclosure.

Referring to FIG. 5, since the information provided by the prediction information preprocessor 257b is related to the distribution of the capacity of the ESS device 105, the AI ESS charge/discharge command generator 257 may add up (e.g., cumulative sum in at least one time unit) all the prediction information from the current (Now) time step to the last time step. For example, if the present is time T0, the AI ESS charge/discharge command generator 257 may add up (e.g., total cumulative sum) all the prediction information from the present to time Tn and use it as the prediction information of the current time point (T0). The time T is a predefined time unit and may be a designated time (e.g., 1 hour). When the reference time unit elapses and it becomes time T1, the AI ESS charge/discharge command generator 257 may add up (e.g., partial cumulative sum) all the prediction information from time T1 to time Tn and use it as the prediction information of the current time point (e.g., T1). When the reference time unit elapses and it becomes time T2, the AI ESS charge/discharge command generator 257 may add up (e.g., partial cumulative sum) all the prediction information from time T2 to time Tn and use it as the prediction information of the current time point (e.g., T2). The AI ESS charge/discharge command generator 257 may set a time greater than TO for the value of Tn. For example, if T0 is 1 hour, Tn may be 24 hours. The AI ESS charge/discharge command generator 257 may update the Tn value if the value of TL (L is a natural number greater than 1) is greater than a certain size. For example, if the L value is greater than half of the n value, the AI ESS charge/discharge command generator 257 may change the n value to a second reference time unit (e.g., 24 hours). For example, the AI ESS charge/discharge command generator 257 may set a 1-hour unit as the first reference time unit and a 24-hour unit as the second reference time unit.

When both renewable energy generation and electricity demand exist, the AI ESS charge/discharge command generator 257 may either use the total sum for each prediction or differentiate between received and transmitted power amounts. For the latter, it may assign different positive and negative signs to renewable energy generation or power demand, and then use the time-step-specific sum of predictions as two separate input variables: one for the sum of positive values and one for the sum of negative values. In addition, for cases where power costs such as electricity rates or basic rates are divided into specific sections, the AI ESS charge/discharge command generator 257 may calculate and use the total sum for each section or the sum of received and transmitted power.

For example, when the solar power facility and the ESS device 105 are installed in the vehicle charge/discharge unit 104, the optimal ESS charge/discharge algorithm or AI model that minimizes the power cost of the vehicle charge/discharge unit 104 may be provided through reinforcement learning. For example, the Korea Electric Power Corporation (KEPCO) has a three-tiered charging rate system for electric vehicles: light load (low rate) from 10 PM on the previous day to 8 AM, medium load (intermediate rate) from 8 AM to 11 AM, from 12 PM to 1 PM, and from 6 PM to 10 PM, and peak load (high rate) from 11 PM to 12 PM and from 1 PM to 6 PM. The basic rate application power is determined by the highest monthly value of the 15-minute average power usage during the medium and peak load time zones. Assuming that there is no solar power generation or electric vehicle charging power, which is uncertain power, the AI ESS charge/discharge command generator 257 may perform the optimal ESS charge/discharge operations as follows: fully charge during the light load time zone, discharge at maximum output during the peak load time zone from 11 PM to 12 PM, charge at maximum output again during the medium load time zone from 12 PM to 1 PM, and fully discharge after 1 PM. However, if solar power generation and electric vehicle charging are included during the ESS charge/discharge operations under the above plan, the basic rate may increase beyond the existing basic rate application power, or the electricity rate for that day or month may rise due to power being transmitted to the KEPCO. Therefore, when training the optimal ESS charge/discharge model using reinforcement learning, it is possible to realize the optimal ESS battery capacity distribution that overcomes the uncertainty of solar power generation and electric vehicle charging, by distinguishing between light, medium, and peak load time zones, as well as between received power and transmitted power, calculating the combined predicted sums of solar power generation and electric vehicle charging, and using them as input variables.

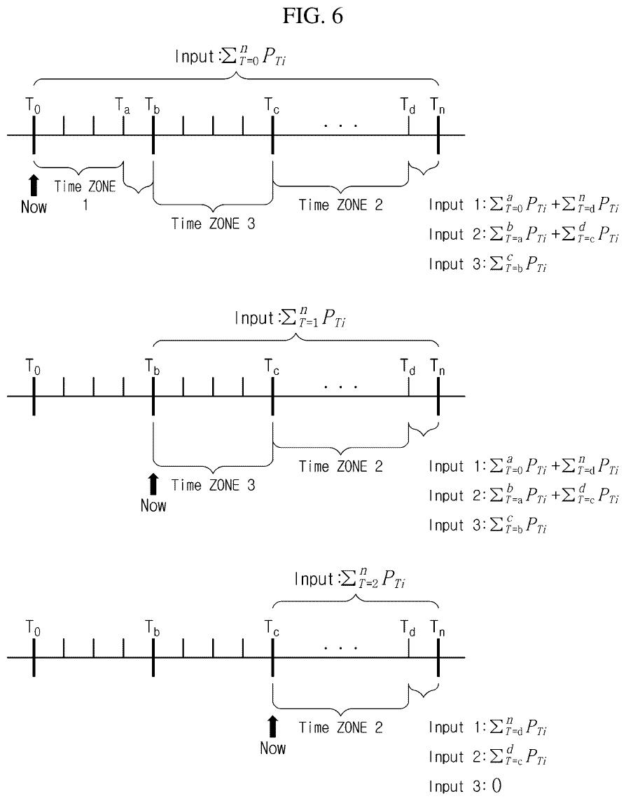

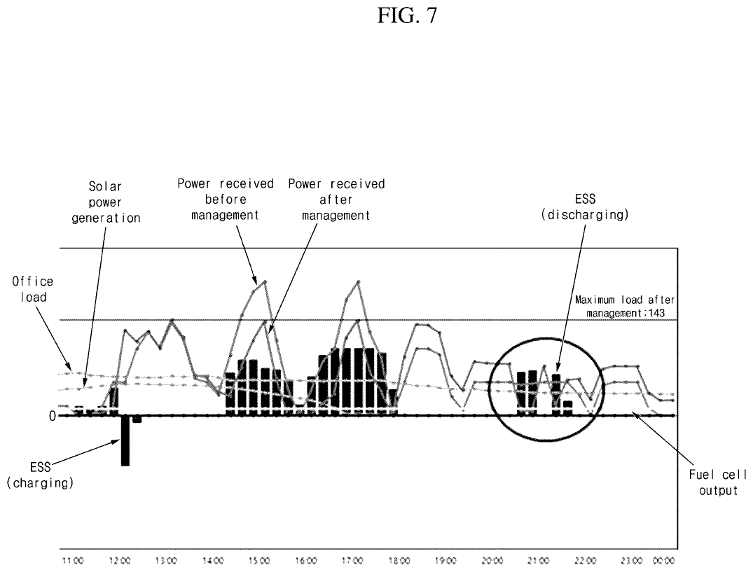

FIG. 6 is a diagram illustrating another example of data input for a reinforcement learning AI model according to an embodiment of the present disclosure.

Referring to FIG. 6, prediction information may be aggregated by time zone that distinguishes the power unit price or peak power application interval. For example, if the power unit price is divided into three time zones during the day and the current time is T0, the AI ESS charge/discharge command generator 257 may aggregate the prediction information by each time zone after T0 and use it as the prediction information for the current point in time (T0). The three time zones are composed of time zone 1, time zone 2, and time zone 3.

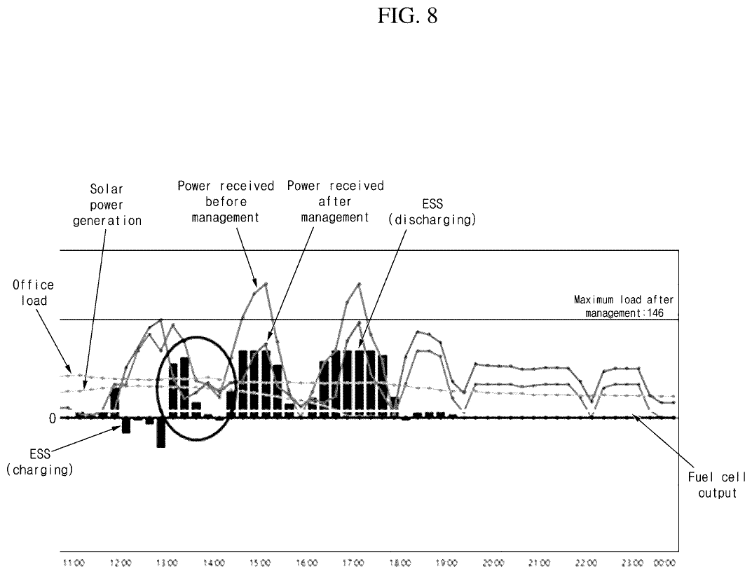

FIG. 7 is a diagram illustrating the charge/discharge results of an example of ESS control based on a prediction of solar power generation and electric vehicle charging power, and FIG. 8 is a diagram illustrating the charge/discharge results of an example of reinforcement learning-based ESS control based on a prediction of solar power generation and electric vehicle charging power based on according to an embodiment of the present disclosure.

As shown in FIG. 7, before applying the reinforcement learning-based control of the ESS device 105, which preprocesses the prediction of power generation or consumption (e.g., solar power generation, electric vehicle charging, office load), due to the inaccuracy of the prediction of solar power generation and electric vehicle charging power, the peak power was expected during the medium load time zone between 18:00 and 22:00, so the charge power of the ESS device 105 was not sufficiently discharged during the peak load time zone. However, it can be seen that the peak power actually did not occur during the medium load time zone between 18:00 and 22:00, so the remaining charge power of the ESS device 105 was discharged around 21:00. In contrast, referring to FIG. 8, it can be seen that when the reinforcement learning-based control of the ESS device 105, which preprocesses the prediction of power generation or consumption (e.g., solar power generation, electric vehicle charging, office load), is applied, the discharge was maximized during the peak load time zone. Comparing before and after applying the reinforcement learning-based control of the ESS device 105 with preprocessing of power generation or consumption predictions, it can be seen that it has the effect of lowering the electricity rate of electric vehicle charging stations.

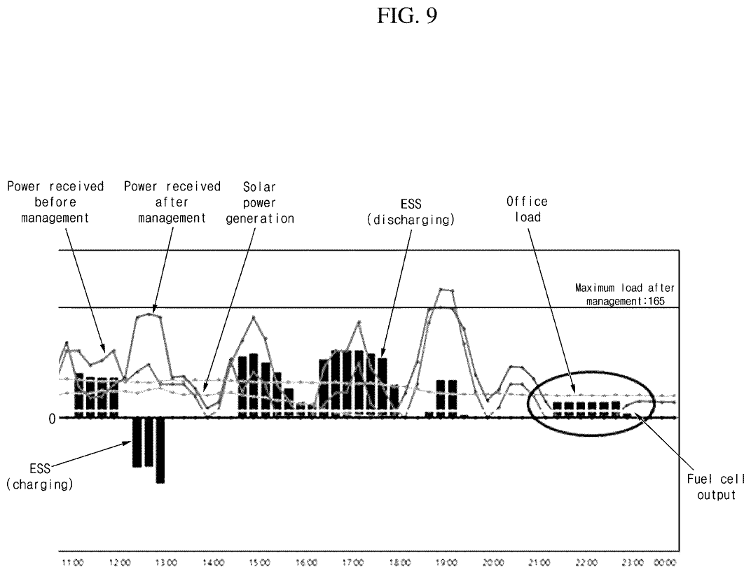

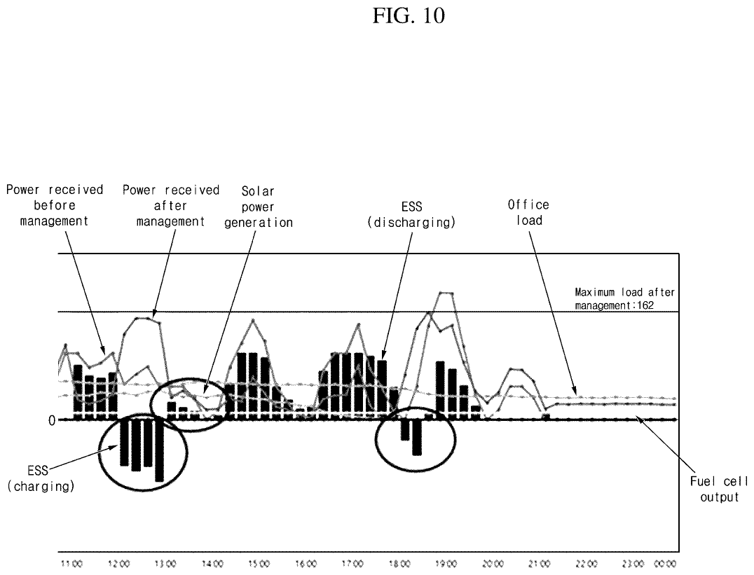

FIG. 9 is a diagram illustrating the charge/discharge results of another example of ESS device control based on a prediction of solar power generation and electric vehicle charging power, and FIG. 10 is a diagram illustrating the charge/discharge results of another example of reinforcement learning-based ESS device control based on a prediction of solar power generation and electric vehicle charging power based on according to an embodiment of the present disclosure.

The examples of FIGS. 9 and 10 illustrate a state in which, in addition to the situations of FIGS. 7 and 8 described above, the basic rate application power is set to be maintained at 170 kW or less as a goal. Referring to FIGS. 9 and 10, it can be seen that since the received power exceeds 170 kW between 18:00 and 20:00, the ESS device 105 discharges during this time zone both before and after applying the reinforcement learning-based control of the ESS device 105 that preprocesses the prediction of power generation or consumption, so that the received power does not exceed 170 kW. However, as shown in FIG. 9, before applying the reinforcement learning-based control of the ESS device 105 that preprocesses the prediction of power generation or consumption (e.g., solar power generation, electric vehicle charging, office load), it can be seen that the ESS device 105 still had residual charge power even after responding to the received power exceeding 170 kW, leading to additional discharge between 21:00 and 23:00. In contrast, as shown in FIG. 10, after applying the reinforcement learning-based control of the ESS device 105 that preprocesses the prediction of power generation or consumption (e.g., solar power generation, electric vehicle charging, office load), it can be seen that intelligent ESS optimal charge/discharge is performed to discharge as much of the charge power of the ESS device 105 as possible during the peak load time zone, and to additionally charge the ESS device 105 between 18:00 and 18:30 during the medium load time zone, thereby replenishing the charge power of the ESS device 105 for discharging when the received power exceeds 170 kW.

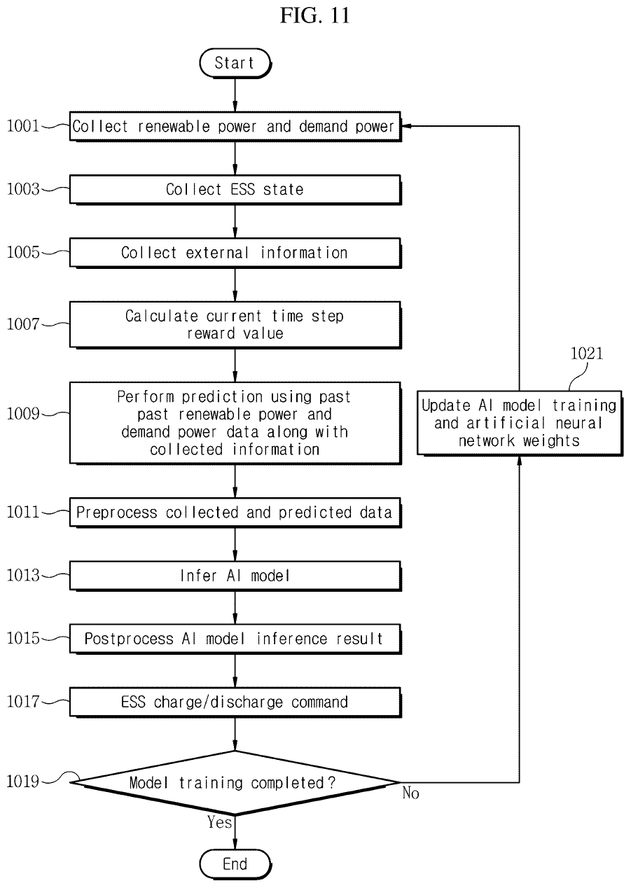

FIG. 11 is a diagram illustrating an example of an AI modeling method related to reinforcement learning-based ESS charge/discharge control according to an embodiment of the present disclosure.

Referring to FIG. 11, in relation to the AI modeling method related to ESS charge/discharge control based on reinforcement learning according to an embodiment, the server processor 250 may collect renewable power and demand power (or load power) in step 1001, collect state information of the ESS device 105 in step 1003, and collect the external information 235 in step 1005. Although the above description explains the order of collecting renewable power and demand power, collecting ESS state, and collecting external information, the present disclosure is not limited thereto. For example, the server processor 250 may change the order of steps 1001 to 1005 described above, or may perform at least two steps simultaneously.

In step 1007, the server processor 250 may calculate the current time step reward value. For example, based on the information collected through steps 1001 to 1005, the server processor 250 may calculate the reward value for the result of applying the previous ESS charge/discharge command to the AI model. For example, the server processor 250 may compare the collected information with a preset reference value (or data prior to applying the AI model). If the result shows an improved outcome, it may calculate a reward value corresponding to a favorable degree, and if the result shows a degraded outcome compared to the previous or reference value, it may calculate a reward value corresponding to an unfavorable degree than the previous or reference value. In this process, the server processor 250 may calculate the magnitude of the favorable degree or the unfavorable degree differently depending on a separation distance from the reference value (or previous data). Meanwhile, the calculation of the reward value in step 1007 may be omitted or performed in the background and applied to the weight update in step 1021.

In step 1009, the server processor 250 may perform the next prediction based on past renewable power and demand power data and currently collected information. For example, the server processor 250 may predict the amount of power that can be generated at the renewable power plant 101 for the next reference time based on the external information 235 and past renewable power information. In addition, the server processor 250 may predict the next load power of the consumer 103 based on the external information 235 and past demand power data. In this regard, the external information 235 includes information on past renewable power generation amount by history (e.g., at least one of location, time, season, temperature, humidity, and wind), and may include information on past demand power consumed by the consumer 103 by history (e.g., at least one of place, time, season, temperature, humidity, and wind). The server processor 250 may identify past external information matching the currently acquired external information 235 and predict the amount of renewable energy generation and demand power under the matched past external information conditions.

In step 1011, the server processor 250 may preprocess the collected and predicted data. For example, the server processor 250 may convert the collected and predicted data into values set by the system. For example, the server processor 250 may calculate the preprocessed values for the collected and predicted data, such as the average value within at least one time reference unit, the difference value from the previous data, or the summation value with previous data. Additionally, the server processor 250 may perform an analysis of the collected and predicted data over multiple time reference units (or a certain number of cumulative time units) to calculate a trend value, such as an increase, decrease, or maintenance of data value.

In step 1013, the server processor 250 may perform AI model inference based on the preprocessed prediction data. For example, the server processor 250 may apply the preprocessed prediction data as input values for the AI model and perform the corresponding inference. For example, the server processor 250 may infer, based on the previous data already stored in the server memory 230, whether applying the preprocessed prediction data will derive a more favorable result (e.g., lower power consumption cost) than before.

In step 1015, the server processor 250 may perform postprocessing on the AI model inference results. For example, if there are maximum and minimum values set by the administrator, the server processor 250 may process the prediction data so that it does not deviate from the maximum or minimum values. Meanwhile, the postprocessing operation in step 1015 may be omitted.

In step 1017, the server processor 250 may generate an ESS charge/discharge command based on the postprocessed results. Next, in step 1019, the server processor may determine whether the model training (or learning) has been completed (e.g., whether a sufficient accumulated reward value has been reached or a predetermined number of training (or learning) has been achieved). If the model training (or learning) has been completed, the server processor 250 may terminate the reinforcement learning-based AI model training (or learning). If the model training has not been completed, the server processor 250 may update the AI model training and artificial neural network weights in step 1021, and return to step 1001 to re-perform the subsequent operations.

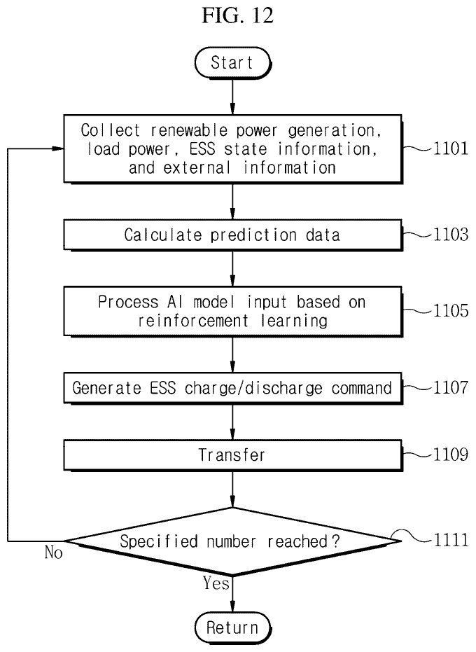

FIG. 12 is a diagram illustrating an example of a method for improving ESS device charge/discharge using a reinforcement learning-based AI model according to an embodiment of the present disclosure.

Referring to FIG. 12, in relation to the method for improving the charging and discharging of an ESS device according to an embodiment of the present disclosure, the server processor 250 may collect, in step 1101, renewable power generation amount, load power amount (or demand power amount), state information of the ESS device 105, and the external information 235. In this regard, the server processor 250 may establish a communication channel with the renewable power plant 101, the ESS device 105, the consumer 103 (or including the vehicle charge/discharge unit 104), and an external server device providing the external information 235, and collect the aforementioned data (e.g., renewable power generation amount, load power amount (or demand power amount), state information of the ESS device 105, and the external information 235) from each component.

In step 1103, the server processor 250 may calculate prediction data to be applied to at least one subsequent time reference unit based on the collected information. For example, the server processor 250 may generate prediction data that predicts power generation amount and load power amount under past external information situations already stored in the server memory 230.

In step 1105, the server processor 250 may process the generated prediction data as input to an AI model that has completed reinforcement learning and is stored in the server memory 230.

In step 1107, the server processor 250 may generate a charge/discharge command for the ESS device 105 based on the value calculated as the output of the AI model, and transfers the charge/discharge command generated to the ESS device 105 in step 1109.

In step 1111, the server processor 250 may determine whether a specified condition is satisfied. If the specified condition is not satisfied, the server processor 250 may return to step 1101 and perform the subsequent process, utilizing the previously used AI model. If the specified condition is satisfied, the server processor 250 may generate a new reinforcement learning-based AI model and perform steps 1101 to 1111 based on the newly generated reinforcement learning-based AI model.

As one example, the server processor 250 may determine whether the number of times prediction data has been generated based on the AI model reaches a predefined number. If the number of times prediction data has been generated using the previous AI model reaches a specified number of times, the server processor 250 may generate a new preprocessed reinforcement learning-based AI model and perform prediction data generation using the newly generated preprocessed reinforcement learning-based AI model.

As another example, when a predefined period of time arrives, the server processor 250 may generate a new preprocessed reinforcement learning-based AI model. For example, the server processor 250 may generate a new preprocessed reinforcement learning-based AI model on a monthly basis, including at least the data applied in real-world situations during the previous one month (or a period exceeding the reference time unit by a certain multiple or more). As yet another example, the server processor 250 may check two conditions (e.g., reaching a specified number of times and the expiration of a usage period) and, if at least one of the two conditions is satisfied, may generate a new preprocessed reinforcement learning-based AI model.

While the description contains many specific implementation details, these should not be construed as limitations on the scope of the present disclosure or of what may be claimed, but rather as descriptions of features that may be specific to particular embodiments of particular disclosure.

Also, although the description describes that operations are performed in a predetermined order with reference to a drawing, it should not be construed that the operations are required to be performed sequentially or in the predetermined order, which is illustrated to obtain a preferable result, or that all of the illustrated operations are required to be performed. In some cases, multi-tasking and parallel processing may be advantageous. Also, it should not be construed that the division of various system components are required in all types of implementation. It should be understood that the described program components and systems are generally integrated as a single software product or packaged into a multiple-software product.

The description shows the best mode of the present disclosure and provides examples to illustrate the present disclosure and to enable a person skilled in the art to make and use the present disclosure. The present disclosure is not limited by the specific terms used herein. Based on the above-described embodiments, one of ordinary skill in the art can modify, alter, or change the embodiments without departing from the scope of the present disclosure.

Accordingly, the scope of the present disclosure should not be limited by the described embodiments and should be defined by the appended claims.

### REFERENCE NUMERALS

10: Power control environment of ESS device
101: Renewable power plant
102: Power transmission/distribution unit
103: Consumer
104: Vehicle charge/discharge unit
105: ESS device
200: Power control unit
210: Server communication circuit
220: Server input unit
230: Server memory
240: Server display
250: Server processor
251: Renewable power generation and state collector
252: Power demand source load power and state collector
253: External information collector
254: ESS state collector
255: Renewable power generation predictor
256: Power demand predictor
257: AI ESS charge/discharge command generator

What is claimed is:

1. A power control device for performing power control of an energy storage system (ESS) device, the power control device comprising:
a server communication circuit configured to form a communication channel with a renewable power plant, a customer, the ESS device, and an external information providing server;
a server memory; and
a server processor functionally connected to the server communication circuit,
the sever processor being configured to:
collect a current power generation amount of the renewable power plant, a current load power amount of the consumer, state information of the ESS device, and environmental information related to power generation of the renewable power plant provided by the external information providing server,
acquire, based on data pre-stored in the server memory, a past power generation amount and a past load power amount in a past external information situation matched to the external information,
calculate current prediction data of a predefined reference time unit by comparing the acquired past power generation amount and the acquired past load power amount with the current power generation amount and the current load power amount,
process the current prediction data as an input for an artificial intelligence model based on reinforcement learning, perform inference, and perform training for generating a charge/discharge command of the ESS device based on a result of the inference.

2. The power control device of claim 1, wherein the server processor is configured to calculate a reward value for a previously applied charge/discharge command of the ESS device based on at least some of the current power generation amount of the renewable power plant, the current load power amount of the consumer, and the state information of the ESS device.

3. The power control device of claim 1, wherein the server processor is configured to perform preprocessing on the prediction data and then process the preprocessed prediction data as the input for the artificial intelligence model.

4. The power control device of claim 3, wherein the server processor is configured to calculate, as the preprocessed prediction data, at least one of an average of current prediction data for a reference time unit, a difference between current prediction data for the reference time unit and prediction data for at least one previous reference time unit, and a sum of current prediction data for the reference time unit and prediction data for at least one previous reference time unit.

5. The power control device of claim 3, wherein the server processor is configured to calculate, as the preprocessed prediction data, at least one of an increase, decrease, and maintenance of data and at least one of a slope value of the increase or decrease, based on prediction data of a plurality of reference time units including the prediction data.

6. The power control device of claim 1, wherein the server processor is configured to perform a post-processing that limits the artificial intelligence model inference to a preset maximum and minimum value range.

7. The power control device of claim 1, wherein the server processor is configured to calculate the prediction data based on a learning-completed artificial intelligence model, provide the prediction data to the ESS device, and if the prediction data calculation satisfies a specified condition, generate a new artificial intelligence model based on reinforcement learning.

8. A method for performing power control of an energy storage system (ESS) device, the method comprising:
collecting, by a server processor of a power control device, a current power generation amount of a renewable power plant, a current load power amount of a consumer, state information of the ESS device, and environmental information related to power generation of the renewable power plant;
acquiring, based on data pre-stored in a server memory of the power control device, a past power generation amount and a past load power amount in a past external information situation matched to external information;
calculating current prediction data of a predefined reference time unit by comparing the acquired past power generation amount and the acquired past load power amount with the current power generation amount and the current load power amount;
processing the current prediction data as an input for an artificial intelligence model based on reinforcement learning;
performing inference on input processing of the artificial intelligence model; and
performing training for generating a charge/discharge command of the ESS device based on a result of the inference.

9. The method of claim 8, further comprising:
calculating a reward value for a previously applied charge/discharge command of the ESS device based on at least some of the current power generation amount of the renewable power plant, the current load power amount of the consumer, and the state information of the ESS device,
wherein the calculated reward value is applied to performing the inference.

10. The method of claim 8, wherein processing as the input for the artificial intelligence model includes:
performing preprocessing on the prediction data and then processing the preprocessed prediction data as the input for the artificial intelligence model.

11. The method of claim 10, wherein processing the preprocessed prediction data as the input for the artificial intelligence model includes:
calculating, as the preprocessed prediction data, at least one of an average of current prediction data for a reference time unit, a difference between current prediction data for the reference time unit and prediction data for at least one previous reference time unit, and a sum of current prediction data for the reference time unit and prediction data for at least one previous reference time unit.

12. The method of claim 10, wherein processing the preprocessed prediction data as the input for the artificial intelligence model includes:
calculating, as the preprocessed prediction data, at least one of an increase, decrease, and maintenance of data and at least one of a slope value of the increase or decrease, based on prediction data of a plurality of reference time units including the prediction data.

13. The method of claim 8, further comprising:
performing a post-processing that limits the artificial intelligence model inference to a preset maximum and minimum value range.

14. The method of claim 8, further comprising:
calculating the prediction data based on a learning-completed artificial intelligence model, providing the prediction data to the ESS device, and if the prediction data calculation satisfies a specified condition, generating a new artificial intelligence model based on reinforcement learning.
